(19) United States
(12) Patent Application Publication
(10) Pub. No.: US 2025/0294672 A1
(43) Pub. Date: Sep. 18, 2025

(54) MULTILAYER SUBSTRATE, MODULE SUBSTRATE, AND ELECTRONIC APPARATUS

(71) Applicant: Murata Manufacturing Co., Ltd., Nagaokakyo-shi (JP)

(72) Inventors: Daigo MATSUBARA, Nagaokakyo-shi (JP); Yoshikazu HIROKARI, Nagaokakyo-shi (JP); Yuuta TANAKA, Nagaokakyo-shi (JP); Tomoki NIIKURA, Nagaokakyo-shi (JP)

(73) Assignee: Murata Manufacturing Co., Ltd., Nagaokakyo-shi (JP)

(21) Appl. No.: 19/039,804

(22) Filed: Jan. 29, 2025

(30) Foreign Application Priority Data
Mar. 13, 2024 (JP) 2024-038635

(51) Int. Cl. H05K 1/02

(52) U.S. Cl. CPC H05K 1/0298

(57) ABSTRACT

A multilayer substrate includes a plurality of resin layers, conductor layers, and interlayer coupling conductors, a multilayer body is configured by stacking the plurality of resin layers and the conductor layers, and an aperture is formed in at least one resin layer so as to form a recess portion in which a part of a resin layer present under the at least one resin layer is exposed. For example, Cu foils are attached to a lower surface of a resin layer present under a resin layer, Cu foils are attached to an upper surface of the resin layer that is an uppermost surface of the multilayer body, and interlayer coupling conductors formed on the resin layer and interlayer coupling conductors formed on the resin layer are directly coupled to each other.

### CROSS-REFERENCE TO RELATED APPLICATION

This application claims priority to Japanese Patent Application No. JP 2024-038635 filed on Mar. 13, 2024. The entire contents of the above-identified application, including the specification, drawings and claims, are incorporated herein by reference in their entirety.

### BACKGROUND OF THE DISCLOSURE

### 1. Field of the Disclosure

The present disclosure relates to a multilayer substrate, a module substrate including the multilayer substrate, and an electronic apparatus including the module substrate.

### 2. Description of the Related Art

International Publication No. 2017/051649 discloses a multilayer substrate including a plurality of resin layers, a conductor layer attached to one surface of each of the resin layers, and an interlayer coupling conductor formed in a predetermined resin layer. In addition, the multilayer substrate in which regions having different thicknesses in the stacking direction are partially formed due to a difference in the number of stacked resin layers is disclosed.

### SUMMARY OF THE DISCLOSURE

In a structure in which regions partially having different thicknesses in the stacking direction are formed due to the difference in the number of stacked resin layers with conductor layers, the thicker parts can be made to have functions of predetermined electronic components. However, since the maximum number of stacked layers required for the circuit configuration of the multilayer substrate is large, manufacturing becomes difficult in terms of stacking accuracy and the number of steps. In addition, assuming the number of stacked resin layers with conductor layers is made as small as possible, an interval between a conductor pattern formed on an inner layer of the multilayer substrate and a conductor pattern formed on an outer layer of the multilayer substrate is inevitably narrowed. This can make it difficult to obtain predetermined electrical characteristics.

Therefore, an object of the present disclosure is to provide, with the limited number of stacked resin layers with conductor layers, a multilayer substrate in which a predetermined interval can be kept between conductor patterns on different layers, to provide a multilayer substrate in which the maximum number of stacked layers required for a circuit configuration is reduced, to provide a module substrate including the multilayer substrate, and to provide an electronic apparatus including the module substrate.

(1) A multilayer substrate according to an example of the present disclosure includes:
a plurality of resin layers;
conductor layers each attached to one surface of each of all of the plurality of resin layers or some of the plurality of resin layers; and
interlayer coupling conductors formed in all of the plurality of resin layers or some of the plurality of resin layers, in which
a multilayer body is configured by stacking the plurality of resin layers and the conductor layers,
at least one resin layer among the plurality of resin layers has an aperture that forms a recess portion (cavity) on a surface of the multilayer body by exposing a part of a resin layer present under the at least one resin layer,
a conductor layer is attached to a lower surface of the resin layer present under the at least one resin layer,
a conductor layer is attached to an upper surface of a resin layer that is an uppermost surface (outer layer) of the multilayer body, and
an interlayer coupling conductor formed on the resin layer present under the at least one resin layer and an interlayer coupling conductor formed on a resin layer disposed at a position of an uppermost layer of the multilayer body are electrically connected to each other.

(2) A module substrate according to an example of the present disclosure includes:
an electronic component having a terminal electrode; and
the multilayer substrate described above, in which
the terminal electrode of the electronic component is electrically coupled to the conductor layer exposed portion of the multilayer substrate with a conductive bonding material interposed between the terminal electrode and the conductor layer exposed portion.

(3) An electronic apparatus according to an example of the present disclosure includes:
the module substrate described above; and
a housing that incorporates the module substrate.

According to the present disclosure, it is possible to obtain, with the limited number of stacked resin layers with conductor layers, a multilayer substrate in which a predetermined interval can be kept between conductor patterns on different layers, to obtain a multilayer substrate in which the maximum number of stacked layers required for a circuit configuration is reduced, to obtain a module substrate including the multilayer substrate, and to obtain an electronic apparatus including the module substrate.

### BRIEF DESCRIPTION OF THE DRAWINGS

FIG. 1 is a sectional view of a multilayer substrate according to a first embodiment;

FIG. 2 is an exploded sectional view of the multilayer substrate according to the first embodiment;

FIG. 3 is a sectional view showing a configuration of a module substrate including the multilayer substrate shown in FIG. 1;

FIG. 4 is a plan view of the module substrate;

FIG. 5 is a sectional view of a multilayer substrate according to a second embodiment;

FIG. 6 is an exploded sectional view of the multilayer substrate according to the second embodiment;

FIG. 7 is a sectional view showing a configuration of a module substrate including the multilayer substrate shown in FIG. 5;

FIG. 8 is a sectional view of a multilayer substrate according to a third embodiment;

FIG. 9 is a sectional view showing a configuration of a module substrate including the multilayer substrate shown in FIG. 8;

FIG. 10 is a sectional view of a multilayer substrate according to a fourth embodiment;

FIG. 11 is a sectional view showing a configuration of a module substrate including the multilayer substrate shown in FIG. 10;

FIG. 12 is a sectional view of a module substrate according to a fifth embodiment; and

FIG. 13 is a sectional view of a module substrate according to a sixth embodiment.

### DESCRIPTION OF THE PREFERRED EMBODIMENTS

Hereinafter, a plurality of aspects for carrying out the present disclosure will be described with reference to the drawings with some specific examples. The same reference numerals will be given to the same locations in the drawings. In consideration of the ease of description or understanding of the main points, a plurality of embodiments will be described for convenience of description, but partial omission, substitution, or combination of the configurations described in different embodiments is possible. In a second embodiment and subsequent embodiments, descriptions about matters common to those in a first embodiment will be omitted, and only different points will be described. Particularly, the same effects and actions achieved by the same configurations will not be repeatedly mentioned in each embodiment.

### First Embodiment

In the first embodiment, a module substrate including a patch antenna, and a multilayer substrate including a module substrate, will be exemplified.

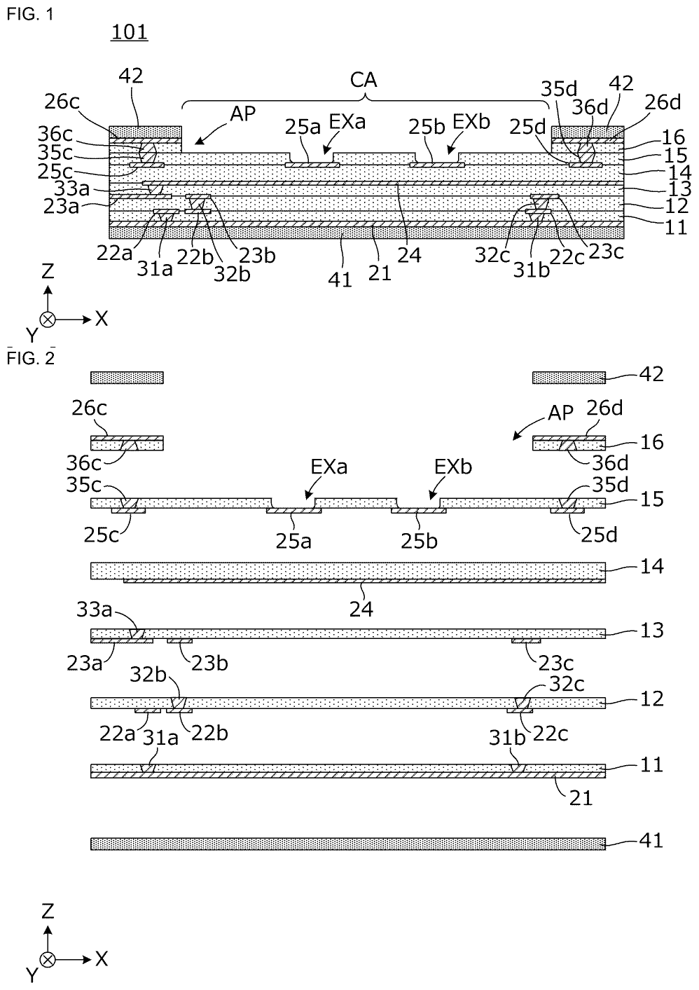

FIG. 1 is a sectional view of a multilayer substrate 101 according to the first embodiment. FIG. 2 is an exploded sectional view of the multilayer substrate 101 according to the first embodiment. In the sectional view, lines appearing in the section (appearing due to cutting) are drawn, and lines present behind the section are not shown. The same applies to each of the embodiments described below. In addition, although a single multilayer substrate is shown in FIGS. 1 and 2, in a middle stage of manufacturing such a single multilayer substrate, a continuum is made up of a plurality of multilayer substrates and is made into a single body by cutting the continuum in a final stage of the manufacturing process or a stage immediately before the final stage. Such a relationship between the continuum and the single body is the same in other drawings.

The multilayer substrate 101 includes a plurality of resin layers 11, 12, 13, 14, 15, and 16, a Cu foil attached to one surface of each of the resin layers 11, 12, 13, 14, 15, and 16, and interlayer coupling conductors formed in the resin layers 11, 12, 13, 15, and 16. These interlayer coupling conductors are made of Cu or Ag, and all of them are formed by, for example, plating.

The above-described conductor layers are already patterned in FIGS. 1 and 2, and form respective predetermined conductor patterns. These Cu foils are examples of a “conductor layer” according to the present disclosure.

As shown in FIG. 2, a Cu foil 21 is attached to the lower surface of the resin layer 11. In addition, in the resin layer 11, interlayer coupling conductors 31a and 31b that penetrate the resin layer 11 and are electrically connected to the Cu foil 21 are formed.

Cu foils 22a, 22b, and 22c are attached to the lower surface of the resin layer 12. In addition, in the resin layer 12, interlayer coupling conductors 32b and 32c that penetrate the resin layer 12 and are electrically connected to the Cu foils 22b and 22c, respectively, are formed.

Cu foils 23a, 23b, and 23c are attached to the lower surface of the resin layer 13. In addition, in the resin layer 13, an interlayer coupling conductor 33a that penetrates the resin layer 13 and is electrically connected to the Cu foil 23a is formed.

A Cu foil 24 is attached to the lower surface of the resin layer 14.

Cu foils 25a, 25b, 25c, and 25d are attached to the lower surface of the resin layer 15. In addition, in the resin layer 15, interlayer coupling conductors 35c and 35d that penetrate the resin layer 15 and are electrically connected to the Cu foils 25c and 25d, respectively, are formed.

Cu foils 26c and 26d are attached to the upper surface of the resin layer 16. In addition, in the resin layer 16, interlayer coupling conductors 36c and 36d that penetrate the resin layer 16 and are electrically connected to the Cu foils 26c and 26d, respectively, are formed.

The interlayer coupling conductor 35c and the interlayer coupling conductor 36c are directly bonded to each other and are electrically connected to each other. In addition, the interlayer coupling conductor 35d and the interlayer coupling conductor 36d are directly bonded to each other and are electrically connected to each other.

In this example, the resin layers 11, 12, 13, 14, 15, and 16 are, for example, thermoplastic resins, and in this example, the resin layers are stacked by bonding resin layers adjacent to each other in the stacking direction and bonding a resin layer and a Cu foil adjacent to each other in the stacking direction. The resin layers 11, 12, 13, 14, 15, and 16 are, for example, a liquid crystal polymer resin (LCP). In this manner, by using a resin material, such as a liquid crystal polymer resin, having a low water absorption rate, a multilayer substrate having high electrical characteristics and various types of reliability can be obtained.

A “multilayer body” is constituted by stacking the resin layers 11, 12, 13, 14, 15, and 16 and the Cu foils attached to the resin layers.

The Cu foils 26c and 26d attached to the resin layer 16 which is the uppermost surface (outer layer) of the multilayer body are formed on the upper surface of the resin layer 16.

As shown in FIGS. 1 and 2, the resin layer 16 has an aperture AP. As a result, the resin layer 16 exposes a part of the resin layer 15 present under the resin layer 16. As shown in FIG. 1, the aperture AP of the resin layer 16 forms a recess portion (cavity) CA in a part of the surface of the multilayer body.

The Cu foils 25c and 25d are attached to the lower surface of the resin layer 15 present under the resin layer 16 in which the aperture AP is formed, and the Cu foils 26c and 26d are attached to the upper surface of the resin layer 16 which is the uppermost surface (outer layer) of the multilayer body.

The interlayer coupling conductors 35c and 35d formed in the resin layer 15 present under the resin layer 16 are electrically connected to the interlayer coupling conductors 36c and 36d formed in the resin layer 16 disposed at a position of the uppermost layer of the multilayer body. That is, the interlayer coupling conductors are directly bonded to each other. As a result, it is possible to increase the interval (the distance in the stacking direction) between the Cu foils 26c and 26d formed on the upper surface of the resin layer 16 which is the uppermost surface (outer layer) of the multilayer body and the Cu foil 24 attached to the lower surface of the resin layer 14.

The resin layer 15 present under the resin layer 16 includes Cu foil exposed portions EXa and EXb in which a part of the Cu foils 25a and 25b attached to the resin layer 15 is exposed on the surface of the multilayer body in the recess portion CA (in the aperture AP). That is, the Cu foil exposed portions EXa and EXb are openings partially formed in the resin layer 15. The Cu foil exposed portions EXa and EXb are examples of a “conductor layer exposed portion” according to the present disclosure.

As shown in FIG. 1, the Cu foil exposed portions EXa and EXb are formed by laser processing, for example, after the multilayer body is formed.

In the example shown in FIG. 1, a protective film 41 having electrical insulating properties is formed to cover the entire lower surface of the multilayer body. In addition, a protective film 42 having electrical insulating properties is formed to cover the outer surface of the Cu foils 26c and 26d on the upper surface of the multilayer body. These protective films 41 and 42 are made of, for example, a polymer compound such as polyimide.

In the example shown in FIGS. 1 and 2, the Cu foils 26c and 26d attached to the upper surface of the resin layer 16 disposed at a position of the uppermost layer of the multilayer body are ground conductor layers, and the pattern of the Cu foil 24 attached to the lower surface of the resin layer 14 present under the resin layer 16 is a signal conductor pattern. In addition, the Cu foil 21 attached to the lower surface of the resin layer 11 is a ground conductor layer. Due to this structure, a strip line is configured by the Cu foil 24 as a signal conductor pattern, the Cu foils 21, 26c, and 26d as ground conductor layers, and the resin layers 11, 12, 13, 14, 15, and 16 between the Cu foil 24 and the Cu foil 21 and between the Cu foil 24 and the Cu foils 26c and 26d.

In a case where the Cu foil 21 is not present or even in a case where the Cu foil 21 is present but is not a ground conductor layer, a microstrip line is configured by the Cu foil 24 as a signal conductor pattern, the Cu foils 26c and 26d as ground conductor layers, and the resin layers 14, 15, and 16 between the Cu foil 24 and the Cu foils 26c and 26d.

As described above, since the interval between the Cu foils 26c and 26d and the Cu foil 24 can be easily increased, capacitance generated between the Cu foils 26c and 26d and the Cu foil 24 can be suppressed while the multilayer substrate has a thin thickness. As a result, the line width of the Cu foil 24, which is a signal conductor pattern, can be increased, and thus the transmission loss of the strip line or the microstrip line can be reduced.

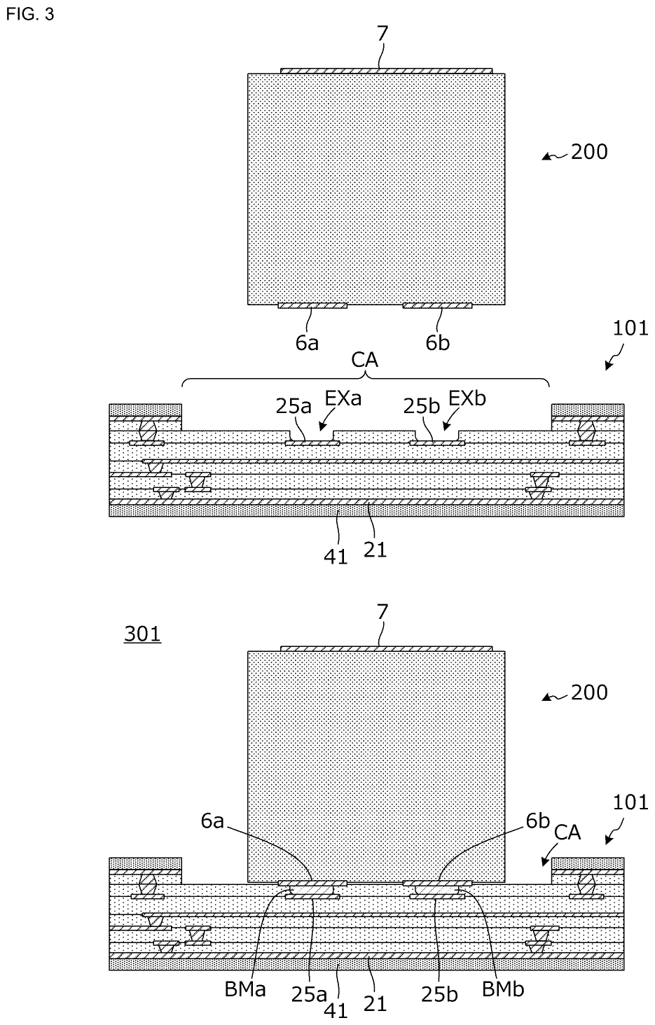

FIG. 3 is a sectional view showing a configuration of a module substrate 301 including the multilayer substrate 101 shown in FIG. 1. The lower part of FIG. 3 is a sectional view of the module substrate 301 according to the present embodiment, and the upper part of FIG. 3 is a sectional view for description in the middle of the manufacturing process.

The module substrate 301 includes the multilayer substrate 101 and an electronic component 200 mounted on the multilayer substrate 101.

As shown in the upper part of FIG. 3, the electronic component 200 has terminal electrodes 6a and 6b on the lower surface. In this example, the electronic component 200 has a rectangular parallelepiped shape, has a radiation electrode 7 on the upper surface, and acts as a patch antenna.

As shown in the lower part of FIG. 3, the terminal electrodes 6a and 6b of the electronic component 200 are electrically coupled to the Cu foils 25a and 25b exposed through the Cu foil exposed portions EXa and EXb, respectively, with conductive bonding materials BMa and BMb interposed therebetween. That is, the electronic component 200 is mounted in the recess portion CA. The conductive bonding materials BMa and BMb are, for example, thermoplastic metals such as solder or conductive adhesives.

In FIG. 3, an example in which the bottom surface of the electronic component 200 is not directly bonded to the resin layer of the multilayer substrate 101 is shown, but the bottom surface other than portions in contact with the conductive bonding materials BMa and BMb may be directly bonded to the resin layer. As a result, the bonding strength of the electronic component 200 to the multilayer substrate 101 can be increased.

As shown in the lower part of FIG. 3, the electronic component 200 does not need a part of the multilayer substrate to act as an electronic component by increasing the number of stacked layers of the multilayer substrate 101, and thus a module substrate having a multilayer substrate in which the maximum number of stacked layers required for a circuit configuration is reduced is obtained.

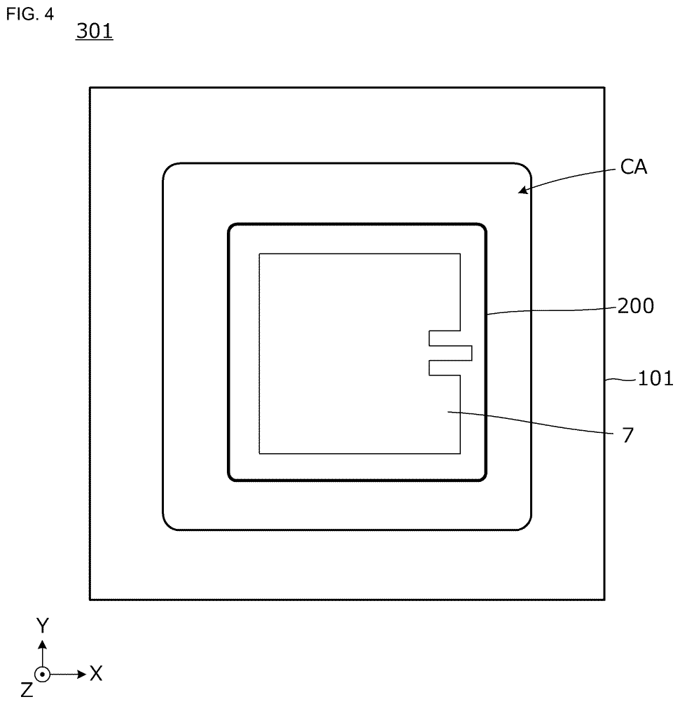

FIG. 4 is a plan view of the module substrate 301. In this example, the multilayer substrate 101 having a rectangular planar shape has the recess portion CA having a rectangular planar shape, and the single electronic component 200 is mounted in the recess portion CA.

The radiation electrode 7 is formed on the upper surface of the electronic component 200, and the electronic component 200 acts as a patch antenna in which the ground conductor layer formed in the vicinity of the lower surface of the electronic component 200 or the Cu foil 21 of the multilayer substrate 101 is used as a ground conductor layer.

In the example shown in FIG. 4, the planar shape of the recess portion CA is similar to the planar shape of the electronic component 200, and the single electronic component 200 is mounted in the recess portion CA, but a plurality of electronic components may be mounted in the recess portion CA.

According to the present embodiment, by having the recess portion CA, the interval between the conductor patterns on different layers can be increased while the number of stacked resin layers and conductor layers is small.

In addition, according to the present embodiment, since a multilayer substrate in which the maximum number of stacked layers required for a circuit configuration is reduced is used, manufacturing is facilitated in terms of stacking accuracy and the number of steps.

In addition, according to the present embodiment, since the electronic component 200 is mounted in the recess portion CA of the multilayer substrate 101, a thin (low-profile) module substrate 301 is obtained as a whole.

In addition, since the resin layers are thermoplastic resins, the layers can be easily stacked together, and a separate adhering step using an adhesive layer is not required, and thus the manufacturing cost can be reduced.

### Second Embodiment

In the second embodiment, a multilayer substrate including an interlayer coupling conductor that is exposed on a surface of a multilayer body in a recess portion, and a module substrate including the multilayer substrate will be exemplified.

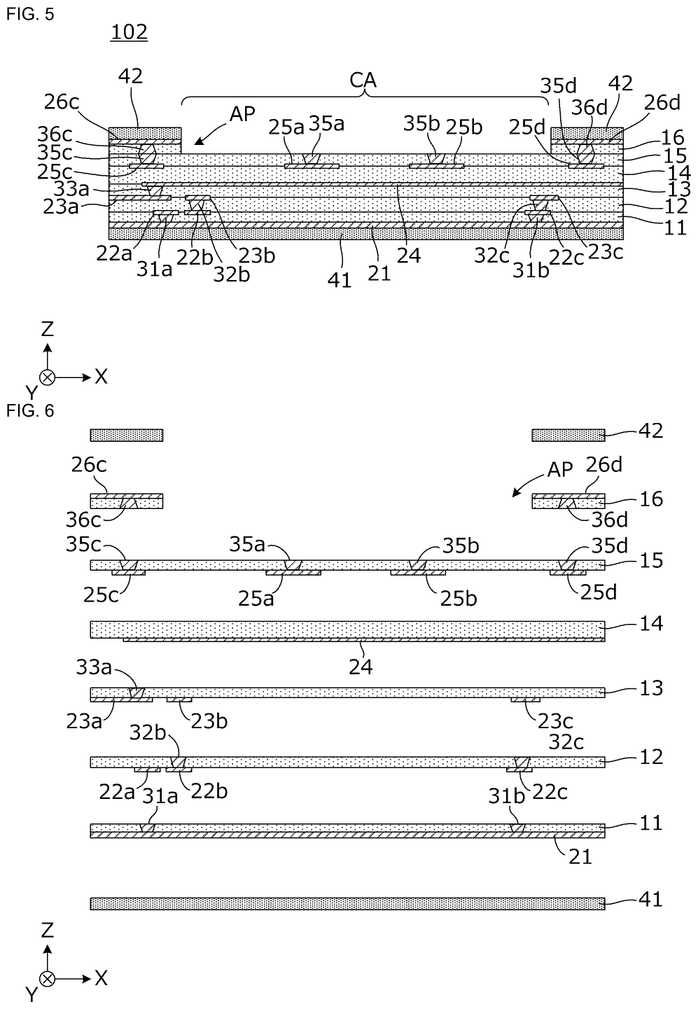

FIG. 5 is a sectional view of a multilayer substrate 102 according to the second embodiment. FIG. 6 is an exploded sectional view of the multilayer substrate 102 according to the second embodiment.

The multilayer substrate 102 includes the plurality of resin layers 11, 12, 13, 14, 15, and 16, the Cu foil attached to one surface of each of the resin layers 11, 12, 13, 14, 15, and 16, and the interlayer coupling conductors formed in the resin layers 11, 12, 13, 15, and 16.

As shown in FIG. 6, the Cu foil 21 is attached to the lower surface of the resin layer 11. In addition, in the resin layer 11, the interlayer coupling conductors 31a and 31b that penetrate the resin layer 11 and are electrically connected to the Cu foil 21 are formed.

The Cu foils 22a, 22b, and 22c are attached to the lower surface of the resin layer 12. In addition, in the resin layer 12, the interlayer coupling conductors 32b and 32c that penetrate the resin layer 12 and are electrically connected to the Cu foils 22b and 22c, respectively, are formed.

The Cu foils 23a, 23b, and 23c are attached to the lower surface of the resin layer 13. In addition, in the resin layer 13, the interlayer coupling conductor 33a that penetrates the resin layer 13 and is electrically connected to the Cu foil 23a is formed.

The Cu foil 24 is attached to the lower surface of the resin layer 14.

The Cu foils 25a, 25b, 25c, and 25d are attached to the lower surface of the resin layer 15. In addition, in the resin layer 15, interlayer coupling conductors 35a, 35b, 35c, and 35d that penetrate the resin layer 15 and are electrically connected to the Cu foils 25a, 25b, 25c, and 25d, respectively, are formed.

The Cu foils 26c and 26d are attached to the upper surface of the resin layer 16. In addition, in the resin layer 16, the interlayer coupling conductors 36c and 36d that penetrate the resin layer 16 and are electrically connected to the Cu foils 26c and 26d, respectively, are formed.

The interlayer coupling conductor 35c and the interlayer coupling conductor 36c are directly bonded to each other and are electrically connected to each other. In addition, the interlayer coupling conductor 35d and the interlayer coupling conductor 36d are directly bonded to each other and are electrically connected to each other.

The multilayer body is constituted by stacking the resin layers 11, 12, 13, 14, 15, and 16 and the Cu foils attached to the resin layers.

As shown in FIGS. 5 and 6, the resin layer 16 has the aperture AP. As a result, the resin layer 16 exposes a part of the resin layer 15 present under the resin layer 16. As shown in FIG. 5, the aperture AP of the resin layer 16 forms the recess portion (cavity) CA in a part of the surface of the multilayer body.

The resin layer 15 present under the resin layer 16 includes the interlayer coupling conductors 35a and 35b that are electrically connected to the Cu foils 25a and 25b attached to the resin layer 15, respectively. That is, the interlayer coupling conductors 35a and 35b are exposed on the surface of the multilayer body in the recess portion (in an aperture).

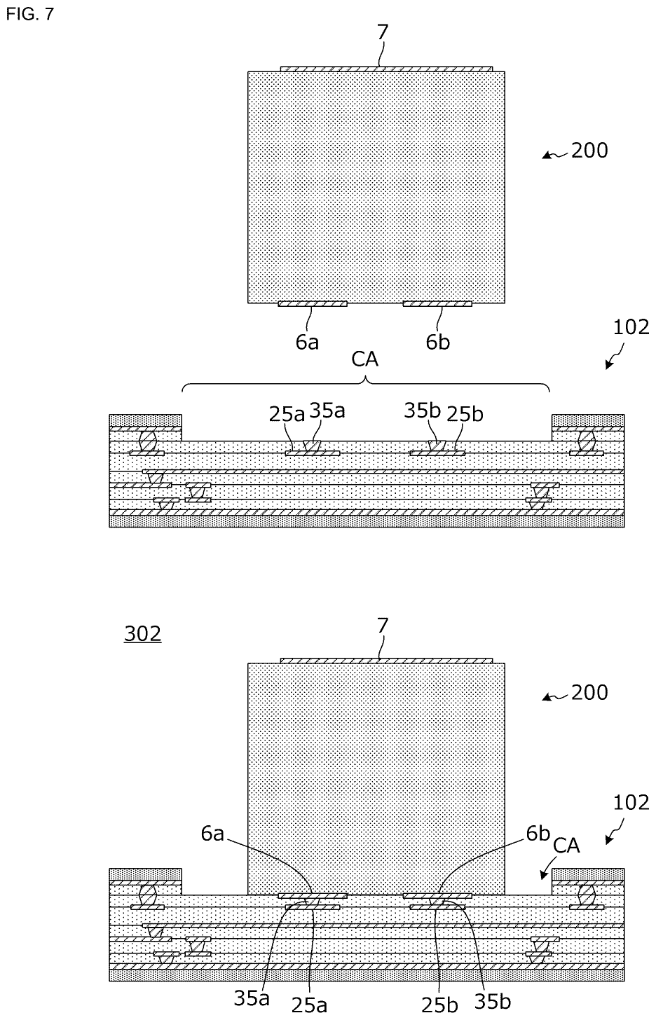

FIG. 7 is a sectional view showing a configuration of a module substrate 302 including the multilayer substrate 102 shown in FIG. 5. The lower part of FIG. 7 is a sectional view of the module substrate 302 according to the present embodiment, and the upper part of FIG. 7 is a sectional view for description in the middle of the manufacturing process.

The module substrate 302 includes the multilayer substrate 102 and the electronic component 200 mounted on the multilayer substrate 102.

As shown in the upper part of FIG. 7, the interlayer coupling conductors 35a and 35b are exposed on the surface of the multilayer body in the recess portion CA. The terminal electrodes 6a and 6b of the electronic component 200 are directly bonded to the interlayer coupling conductors 35a and 35b. For example, the terminal electrodes 6a and 6b of the electronic component 200 are made of Cu, and are electrically connected to the interlayer coupling conductors 35a and 35b made of Cu or Ag. As a result, the electronic component 200 is mounted on the recess portion CA.

The configurations of the other respective portions are the same as those shown in the first embodiment.

According to the present embodiment, the terminal electrodes 6a and 6b of the electronic component 200 are electrically connected to the interlayer coupling conductors 35a and 35b by Cu or Ag, that is, the terminal electrodes 6a and 6b are electrically connected through the interlayer coupling conductors partially containing a conductor made of elemental Cu or Ag. Thus, the terminal electrodes 6a and 6b can be electrically connected with lower impedance than the case where the terminal electrodes 6a and 6b are electrically connected only through solder, for example, and the electrical characteristics are improved. In addition, the distance between the terminal electrodes 6a and 6b of the electronic component 200 and the Cu foils 25a and 25b of the multilayer substrate 102 can be reduced, and thus the electrical resistance can be reduced, and accordingly, the electrical characteristics are improved.

In FIG. 7, since the substantially entire bottom surface, other than portions bonded to the interlayer coupling conductors 35a and 35b, of the electronic component 200 is directly bonded to the resin layer of the multilayer substrate 102, the bonding strength of the electronic component 200 to the multilayer substrate 102 is high.

The other effects and actions are the same as the effects and actions in the multilayer substrate and the module substrate shown in the first embodiment.

### Third Embodiment

In a third embodiment, a multilayer substrate including a plurality of resin layers provided with apertures for forming a recess portion, and a module substrate including the multilayer substrate will be exemplified.

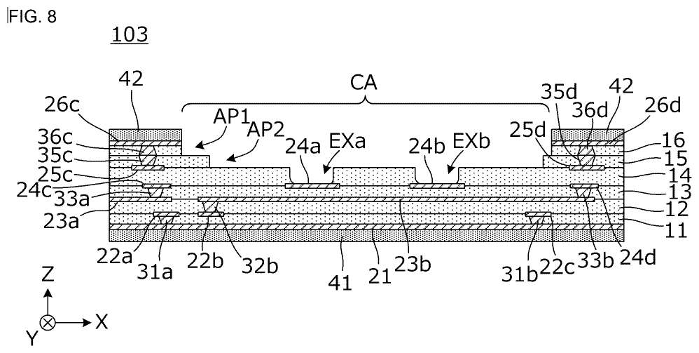

FIG. 8 is a sectional view of a multilayer substrate 103 according to the third embodiment.

The multilayer substrate 103 includes the plurality of resin layers 11, 12, 13, 14, 15, and 16, the Cu foil attached to one surface of each of the resin layers 11, 12, 13, 14, 15, and 16, and the interlayer coupling conductors formed in the resin layers 11, 12, 13, 15, and 16.

The Cu foil 21 is attached to the lower surface of the resin layer 11. In addition, in the resin layer 11, the interlayer coupling conductors 31a and 31b that penetrate the resin layer 11 and are electrically connected to the Cu foil 21 are formed.

The Cu foils 22a, 22b, and 22c are attached to the lower surface of the resin layer 12. In addition, in the resin layer 12, the interlayer coupling conductor 32b that penetrates the resin layer 12 and is electrically connected to the Cu foil 22b is formed.

The Cu foils 23a and 23b are attached to the lower surface of the resin layer 13. In addition, the interlayer coupling conductor 33a that penetrates the resin layer 13 and is electrically connected to the Cu foil 23a and the interlayer coupling conductor 33b that is electrically connected to the Cu foil 23b are formed in the resin layer 13.

Cu foils 24a, 24b, 24c, and 24d are attached to the lower surface of the resin layer 14.

The Cu foils 25c and 25d are attached to the lower surface of the resin layer 15. In addition, in the resin layer 15, the interlayer coupling conductors 35c and 35d that penetrate the resin layer 15 and are electrically connected to the Cu foils 25c and 25d, respectively, are formed.

The Cu foils 26c and 26d are attached to the upper surface of the resin layer 16. In addition, in the resin layer 16, the interlayer coupling conductors 36c and 36d that penetrate the resin layer 16 and are electrically connected to the Cu foils 26c and 26d, respectively, are formed.

The interlayer coupling conductor 35c and the interlayer coupling conductor 36c are directly bonded to each other and are electrically connected to each other. In addition, the interlayer coupling conductor 35d and the interlayer coupling conductor 36d are directly bonded to each other and are electrically connected to each other.

The resin layer 16 has an aperture AP1. In addition, the resin layer 15 has an aperture AP2. As a result, the resin layers 15 and 16 expose a part of the resin layer 14 present under the resin layers 15 and 16. As shown in FIG. 8, the apertures AP2 and AP1 of the resin layers 15 and 16 form the recess portion (cavity) CA in a part of the surface of the multilayer body.

The resin layer 14 includes the Cu foil exposed portions EXa and EXb that expose a part of the Cu foils 24a and 24b attached to the resin layer 14 on the surface of the multilayer body in the recess portion CA (in the aperture AP). That is, the Cu foil exposed portions EXa and EXb are openings partially formed in the resin layer 14.

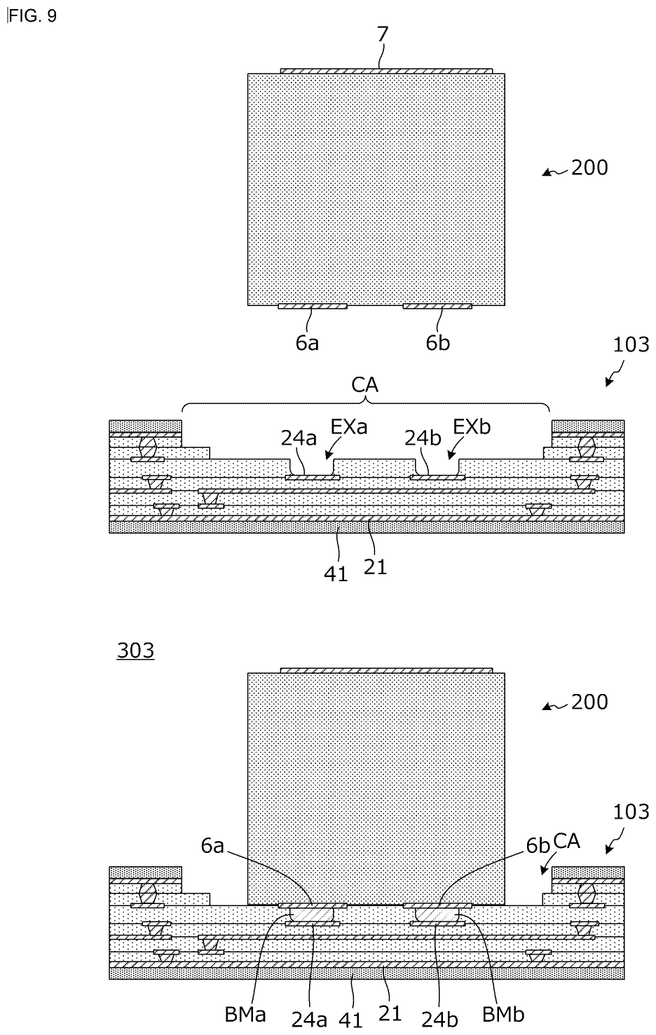

FIG. 9 is a sectional view showing a configuration of a module substrate 303 including the multilayer substrate 103 shown in FIG. 8. The lower part of FIG. 9 is a sectional view of the module substrate 303 according to the present embodiment, and the upper part of FIG. 9 is a sectional view for description in the middle of the manufacturing process.

As shown in the lower part of FIG. 9, the terminal electrodes 6a and 6b of the electronic component 200 are electrically coupled to the Cu foils 24a and 24b exposed through the Cu foil exposed portions EXa and EXb, respectively, with the conductive bonding materials BMa and BMb interposed therebetween. That is, the electronic component 200 is mounted in the recess portion CA. The conductive bonding materials BMa and BMb are, for example, thermoplastic metals such as solder or conductive adhesives.

According to the present embodiment, since the electronic component 200 is mounted in the deeper recess portion CA, that is, the electronic component 200 is mounted in the multilayer substrate part having a small number of stacked layers, the position accuracy of the mounting electrode is high. As a result, it is easy to mount the electronic component 200. In addition, the mounting position accuracy of the mounting component is improved in relation to this.

In addition, since the electronic component 200 is mounted in the deeper recess portion CA, the thinner module substrate 303 is obtained as a whole. Other effects and actions are as described in the first embodiment.

### Fourth Embodiment

In a fourth embodiment, a multilayer substrate having a different configuration from that in the third embodiment, which includes a plurality of resin layers provided with apertures in order to form a recess portion, and a module substrate including the multilayer substrate is exemplified.

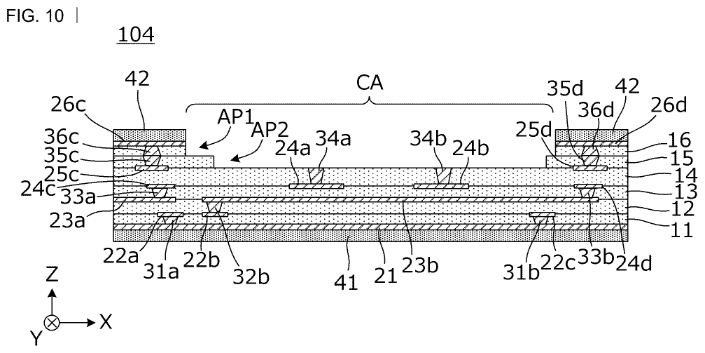

FIG. 10 is a sectional view of a multilayer substrate 104 according to the fourth embodiment.

The multilayer substrate 104 includes the plurality of resin layers 11, 12, 13, 14, 15, and 16, the Cu foil attached to one surface of each of the resin layers 11, 12, 13, 14, 15, and 16, and the interlayer coupling conductors formed in the resin layers 11, 12, 13, 15, and 16.

The Cu foil 21 is attached to the lower surface of the resin layer 11. In addition, in the resin layer 11, the interlayer coupling conductors 31a and 31b that penetrate the resin layer 11 and are electrically connected to the Cu foil 21 are formed.

The Cu foils 22a, 22b, and 22c are attached to the lower surface of the resin layer 12. In addition, in the resin layer 12, the interlayer coupling conductors 32b and 32c that penetrate the resin layer 12 and are electrically connected to the Cu foils 22b and 22c, respectively, are formed.

The Cu foils 23a and 23b are attached to the lower surface of the resin layer 13. In addition, the interlayer coupling conductor 33a that penetrates the resin layer 13 and is electrically connected to the Cu foil 23a and the interlayer coupling conductor 33b that is electrically connected to the Cu foil 23b are formed in the resin layer 13.

The Cu foils 24a, 24b, 24c, and 24d are attached to the lower surface of the resin layer 14. In addition, in the resin layer 14, interlayer coupling conductors 34a and 34b that penetrate the resin layer 14 and are electrically connected to the Cu foils 24a and 24b, respectively, are formed.

The Cu foils 25c and 25d are attached to the lower surface of the resin layer 15. In addition, in the resin layer 15, the interlayer coupling conductors 35c and 35d that penetrate the resin layer 15 and are electrically connected to the Cu foils 25c and 25d, respectively, are formed.

The Cu foils 26c and 26d are attached to the upper surface of the resin layer 16. In addition, in the resin layer 16, the interlayer coupling conductors 36c and 36d that penetrate the resin layer 16 and are electrically connected to the Cu foils 26c and 26d, respectively, are formed.

The interlayer coupling conductor 35c and the interlayer coupling conductor 36c are directly bonded to each other and are electrically connected to each other. In addition, the interlayer coupling conductor 35d and the interlayer coupling conductor 36d are directly bonded to each other and are electrically connected to each other.

The resin layer 16 has the aperture AP1. In addition, the resin layer 15 has the aperture AP2. As a result, the interlayer coupling conductors 34a and 34b are exposed. As shown in FIG. 10, the apertures AP2 and AP1 of the resin layers 15 and 16 form the recess portion (cavity) CA in a part of the surface of the multilayer body.

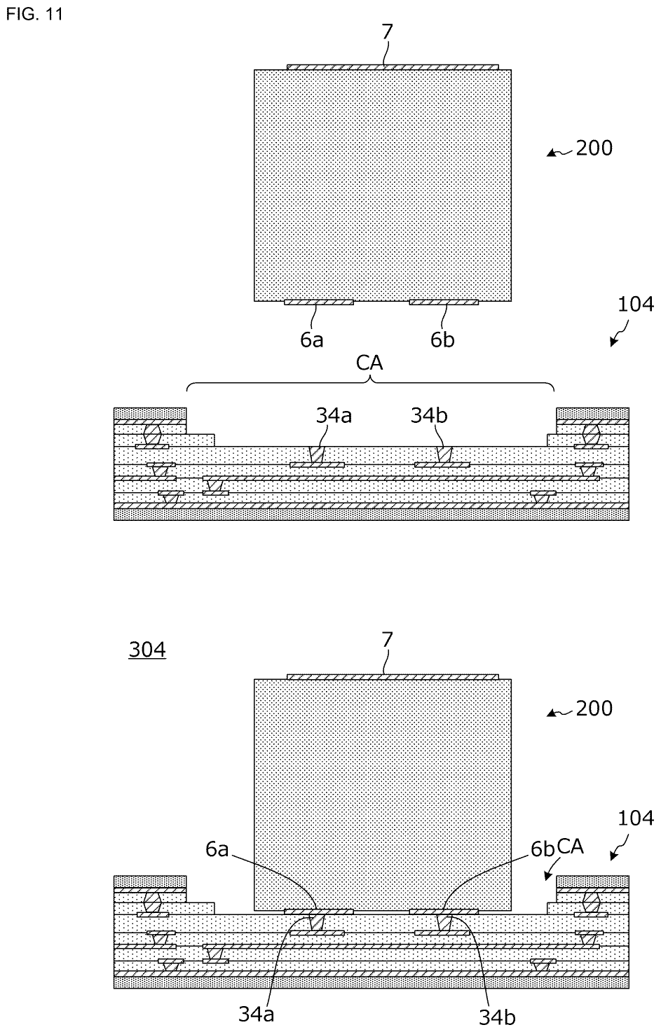

FIG. 11 is a sectional view showing a configuration of a module substrate 304 including the multilayer substrate 104 shown in FIG. 10. The lower part of FIG. 11 is a sectional view of the module substrate 304 according to the present embodiment, and the upper part of FIG. 11 is a sectional view for description in the middle of the manufacturing process.

As shown in the upper part of FIG. 11, the interlayer coupling conductors 34a and 34b are exposed on the surface of the multilayer body in the recess portion CA. The terminal electrodes 6a and 6b of the electronic component 200 are directly bonded to the interlayer coupling conductors 34a and 34b, respectively. As a result, the electronic component 200 is mounted on the recess portion CA.

According to the present embodiment, since the electronic component 200 is mounted in the deeper recess portion CA, the thinner module substrate 304 is obtained as a whole. The configurations of the other respective portions are the same as those shown in the second embodiment. In addition, the effects and actions of the configuration are the same as the effects and actions in the multilayer substrate and the module substrate shown in the second embodiment.

### Fifth Embodiment

In a fifth embodiment, a multilayer substrate having a protective film different in configuration from the protective film in the above-described embodiments and a module substrate including the multilayer substrate will be exemplified.

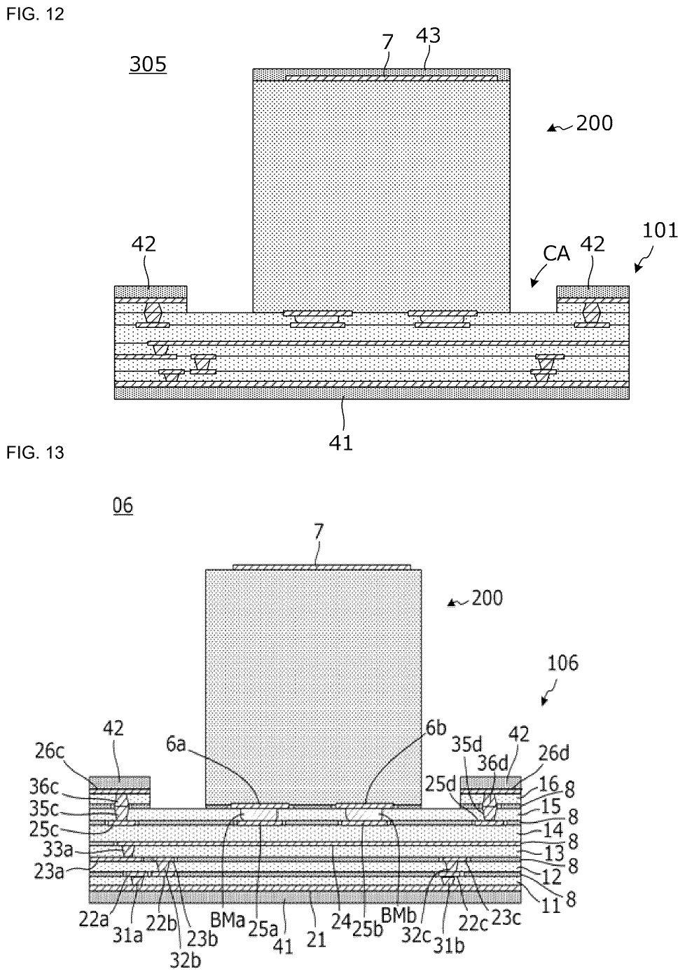

FIG. 12 is a sectional view of a module substrate 305 according to the fifth embodiment. The module substrate 305 includes the multilayer substrate 101 and the electronic component 200. The multilayer substrate 101 is the same as the multilayer substrate 101 shown in the first embodiment. A configuration of a basic part of the electronic component 200 is the same as that of the electronic component 200 shown in the first embodiment.

In the present embodiment, a protective film 43 having electrical insulating properties is formed on the upper surface of the electronic component 200. The radiation electrode 7 is protected by the protective film 43. As described above, the protective film may be formed to cover the electronic component 200.

In the example shown in FIG. 12, the protective film 42 is not formed in the recess portion CA but may be formed in the recess portion CA. Furthermore, a protective film may be formed on the entire outer surface of the electronic component 200.

### Sixth Embodiment

In a sixth embodiment, a multilayer substrate in which a plurality of resin layers and conductor layers are stacked with adhesive layers interposed therebetween, and a module substrate including the multilayer substrate will be exemplified.

FIG. 13 is a sectional view of a module substrate 306 according to the sixth embodiment.

The module substrate 306 includes the multilayer substrate 106 and the electronic component 200 mounted on the multilayer substrate 106. The multilayer substrate 106 includes the plurality of resin layers 11, 12, 13, 14, 15, and 16, the Cu foil attached to one surface of each of the resin layers 11, 12, 13, 14, 15, and 16, and the interlayer coupling conductors formed in the resin layers 11, 12, 13, 15, and 16.

The resin layers 11, 12, 13, 14, 15, and 16 are, for example, thermosetting resins, and in this example, resin layers adjacent to each other in the stacking direction are bonded to each other, and a resin layer and a Cu foil adjacent to each other in the stacking direction are bonded to each other, by adhesion with the adhesive layer 8 interposed therebetween to form a multilayer body.

As shown in the present embodiment, in the multilayer substrate, a plurality of resin layers and conductor layers may be stacked with adhesive layers interposed therebetween. In addition, the electronic component 200 may be adhered in the recess portion CA of the multilayer substrate 106 with the adhesive layer 8 interposed therebetween.

### Seventh Embodiment

In a seventh embodiment, an electronic apparatus according to the present disclosure will be exemplified.

The electronic apparatus according to the present disclosure includes any of the module substrates shown in the first embodiment to the sixth embodiment and a housing that incorporates the module substrate.

The electronic component included in the module substrate includes, for example, a patch antenna, a chip capacitor for impedance matching of a signal transmission line coupled to the patch antenna, a power amplifier IC that outputs a transmission signal to the patch antenna, a signal amplifier IC that amplifies a reception signal of the patch antenna, and the like.

The housing that incorporates the module substrate has a size and a shape that allow the module substrate to be incorporated. In addition, assuming the electronic component communicates with or is electromagnetic field coupled with an external device, at least the portion is made of a non-conductive body or a non-magnetic body.

Although various embodiments according to the present disclosure have been described so far, all of these are examples, and the presentation of these embodiments is not intended to limit the scope of the present disclosure. In the embodiments according to the present disclosure, various omissions, substitutions, and changes can be made without departing from the gist of the disclosure. The embodiments in which various omissions, substitutions, and changes are made are included in the scope of the present disclosure and the gist of the present disclosure, and are included in the disclosure described in the claims of the present application and the scope of equivalents thereof.

For example, the base material of the electronic component 200 shown in FIGS. 3, 7, 9, 11, 12, and 13 may be any material suitable for the electrical characteristics of the electronic component, unlike the resin materials of the multilayer substrates 101, 102, 103, 104, and 106, but the present disclosure is not limited thereto. That is, the base material of the electronic component and the resin layer may be made of different materials, but the base material of the electronic component 200 may be the same material as the resin materials of the multilayer substrates 101, 102, 103, 104, and 106. As a result, a high adhesion strength is obtained between the multilayer substrate and the electronic component. For example, the resin materials of the multilayer substrates 101, 102, 103, 104, and 106 and the base material of the electronic component 200 may also be a liquid crystal polymer resin.

Whether the resin materials are the same type can be confirmed by Fourier transform infrared spectroscopy (FT-IR). That is, assuming a spectrum is obtained by Fourier transform infrared spectroscopy (FT-IR) and the peaks of the spectrum are the same for the electronic component 200 and the multilayer substrate, it can be confirmed that the electronic component 200 and the multilayer substrate are made of the same type of resin material.

In addition, in a case of the thermoplastic resin, resin materials of the same type have a small difference in melting point. Whether the resin portion of the multilayer substrate and the resin portion of the electronic component 200 are the same resin material can be confirmed by an endothermic peak of differential scanning calorimetry (DSC). Specifically, in a case where a difference in melting point between two resin materials is within 5° C. assuming a resin material is heated at a temperature rising rate of 10° C./min using DSC8230 manufactured by Rigaku Corporation, melted, cooled, and heated again at a temperature rising rate of 10° C./min, the resin material can be regarded as the same resin material.

In addition, in each of the embodiments, the signal line conductor pattern and the ground conductor layer are formed to configure the microstrip line or the triplate-type strip line, but the present disclosure is not limited to those including such a transmission line portion.

In addition, in each of the embodiments, the example in which the electronic component including the patch antenna is used has been described, but the present disclosure can also be applied to various other electronic components.

The multilayer substrate, the module substrate, and the electronic apparatus according to the present disclosure may be provided in the following respective aspects.

<1>

A multilayer substrate including:
a plurality of resin layers;
conductor layers each attached to one surface of each of all of the plurality of resin layers or some of the plurality of resin layers; and
interlayer coupling conductors formed in all of the plurality of resin layers or some of the plurality of resin layers, in which
a multilayer body is configured by stacking the plurality of resin layers and the conductor layers,
at least one resin layer among the plurality of resin layers has an aperture that forms a recess portion (cavity) on a surface of the multilayer body by exposing a part of a resin layer present under the at least one resin layer,
a conductor layer is attached to a lower surface of the resin layer present under the at least one resin layer,
a conductor layer is attached to an upper surface of a resin layer that is an uppermost surface (outer layer) of the multilayer body, and
an interlayer coupling conductor formed on the resin layer present under the at least one resin layer and an interlayer coupling conductor formed on a resin layer disposed at a position of an uppermost layer of the multilayer body are electrically connected to each other.
   <2>

The multilayer substrate according to <1>, in which
the plurality of resin layers and the conductor layers are stacked by bonding resin layers to each other and bonding a resin layer and a conductor layer to each other.
   <3>

The multilayer substrate according to <1>, in which
the plurality of resin layers and the conductor layers are stacked with adhesive layers interposed between the plurality of resin layers and the conductor layers.
   <4>

The multilayer substrate according to any one of <1> to <3>, further including
a conductor layer exposed portion that exposes a part of a conductor layer attached to a resin layer positioned on a bottom surface of the recess portion among the plurality of resin layers to a surface of the multilayer body in the recess portion (in an aperture).
   <5>

The multilayer substrate according to any one of <1> to <3>, in which
a resin layer positioned on a bottom surface of the recess portion among the plurality of resin layers includes an interlayer coupling conductor exposed on a surface of the multilayer body in the recess portion (in an aperture).
   <6>

The multilayer substrate according to any one of <1> to <5>, in which
a conductor layer attached to the upper surface of the resin layer disposed at the position of the uppermost layer of the multilayer body is a ground conductor layer, and
a pattern of a conductor layer attached to a lower surface of a resin layer present inside the multilayer body is a signal conductor pattern.
   <7>

A module substrate including:
an electronic component having a terminal electrode; and
the multilayer substrate according to <4>, in which
the terminal electrode of the electronic component is electrically coupled to the conductor layer exposed portion with a conductive bonding material interposed between the terminal electrode and the conductor layer exposed portion (that is, the electronic component is mounted on the recess portion).
   <8>

A module substrate including:
an electronic component having a terminal electrode; and
the multilayer substrate according to <5>, in which
the terminal electrode of the electronic component is directly bonded to the interlayer coupling conductor exposed on the surface of the multilayer body in the recess portion (that is, the electronic component is mounted on the recess portion).
   <9>

The module substrate according to <7> or <8>, in which
a base material of the electronic component and the resin layers are formed of a same material.
   <10>

The module substrate according to <7> or <8>, in which
a base material of the electronic component and the resin layers are formed of different materials.
   <11>

The module substrate according to <7> or <8>, in which
a material of the resin layers is a thermoplastic resin.
   <12>

The module substrate according to <7> or <8>, in which
a material of the resin layers is a liquid crystal polymer resin.
   <13>

An electronic apparatus including:
the module substrate according to any one of <7> to <12>; and a housing that incorporates the module substrate.

What is claimed is:

1. A multilayer substrate comprising:
a plurality of resin layers;
conductor layers each attached to one surface of each of all of the plurality of resin layers or some of the plurality of resin layers; and
interlayer coupling conductors formed in all of the plurality of resin layers or some of the plurality of resin layers, wherein
a multilayer body is configured by stacking the plurality of resin layers and the conductor layers,
at least one resin layer among the plurality of resin layers has an aperture that forms a recess portion on a surface of the multilayer body by exposing a part of a resin layer present under the at least one resin layer,
a conductor layer is attached to a lower surface of the resin layer present under the at least one resin layer,
a conductor layer is attached to an upper surface of a resin layer that is an uppermost surface of the multilayer body, and
an interlayer coupling conductor formed on the resin layer present under the at least one resin layer and an interlayer coupling conductor formed on a resin layer disposed at a position of an uppermost layer of the multilayer body are electrically connected to each other.

2. The multilayer substrate according to claim 1, wherein
the plurality of resin layers and the conductor layers are stacked by bonding resin layers to each other and bonding a resin layer and a conductor layer to each other.

3. The multilayer substrate according to claim 1, wherein
the plurality of resin layers and the conductor layers are stacked with adhesive layers interposed between the plurality of resin layers and the conductor layers.

4. The multilayer substrate according to claim 3, further comprising
a conductor layer exposed portion that exposes a part of a conductor layer attached to a resin layer positioned on a bottom surface of the recess portion among the plurality of resin layers to a surface of the multilayer body in the recess portion.

5. The multilayer substrate according to claim 3, wherein
a resin layer positioned on a bottom surface of the recess portion among the plurality of resin layers includes an interlayer coupling conductor exposed on a surface of the multilayer body in the recess portion.

6. The multilayer substrate according to claim 3, wherein
a conductor layer attached to the upper surface of the resin layer disposed at the position of the uppermost layer of the multilayer body is a ground conductor layer, and
a pattern of a conductor layer attached to a lower surface of a resin layer present inside the multilayer body is a signal conductor pattern.

7. A module substrate comprising:
an electronic component having a terminal electrode; and
the multilayer substrate according to claim 4, wherein
the terminal electrode of the electronic component is electrically coupled to the conductor layer exposed portion with a conductive bonding material interposed between the terminal electrode and the conductor layer exposed portion.

8. A module substrate comprising:
an electronic component having a terminal electrode; and
the multilayer substrate according to claim 5, wherein
the terminal electrode of the electronic component is directly bonded to the interlayer coupling conductor exposed on the surface of the multilayer body in the recess portion.

9. The module substrate according to claim 7, wherein
a base material of the electronic component and the resin layers are formed of a same material.

10. The module substrate according to claim 8, wherein
a base material of the electronic component and the resins layer are formed of a same material.

11. The module substrate according to claim 7, wherein
a base material of the electronic component and the resin layers are formed of different materials.

12. The module substrate according to claim 8, wherein
a base material of the electronic component and the resin layers are formed of different materials.

13. The module substrate according to claim 7, wherein
a material of the resin layers is a thermoplastic resin.

14. The module substrate according to claim 8, wherein
a material of the resin layers is a thermoplastic resin.

15. The module substrate according to claim 7, wherein
a material of the resin layers is a liquid crystal polymer resin.

16. The module substrate according to claim 8, wherein
a material of the resin layers is a liquid crystal polymer resin.

17. An electronic apparatus comprising:
the module substrate according to claim 7; and
a housing that incorporates the module substrate.

18. An electronic apparatus comprising:
the module substrate according to claim 8; and
a housing that incorporates the module substrate.

19. The multilayer substrate according to claim 1, further comprising
a conductor layer exposed portion that exposes a part of a conductor layer attached to a resin layer positioned on a bottom surface of the recess portion among the plurality of resin layers to a surface of the multilayer body in the recess portion.

20. The multilayer substrate according to claim 1, wherein
a resin layer positioned on a bottom surface of the recess portion among the plurality of resin layers includes an interlayer coupling conductor exposed on a surface of the multilayer body in the recess portion.
